(19) United States
(12) Patent Application Publication
(10) Pub. No.: US 2024/0065080 A1
(43) Pub. Date: Feb. 22, 2024

(54) DISPLAY DEVICE

(71) Applicant: Samsung Display Co., Ltd., Yongin-si (KR)

(72) Inventors: Hyuneok Shin, Yongin-si (KR); Juhyun Lee, Yongin-si (KR)

(21) Appl. No.: 18/300,228

(22) Filed: Apr. 13, 2023

(30) Foreign Application Priority Data
Aug. 18, 2022 (KR) 10-2022-0103480

(51) Int. Cl. H10K 59/80; H10K 59/122

(52) U.S. Cl. CPC H10K 59/8792; H10K 59/122; H10K 59/873

(57) ABSTRACT

For a display apparatus for improving visibility by preventing or reducing reflection of external light, provided is a display apparatus including a pixel electrode, an emission layer on the pixel electrode, an opposite electrode covering the emission layer, and a low-reflection layer on the opposite electrode and overlapping the emission layer, wherein the low-reflection layer includes an oxide including molybdenum.

### CROSS-REFERENCE TO RELATED APPLICATION

This application claims priority to and the priority of Korean Patent Application No. 10-2022-0103480, filed on Aug. 18, 2022, in the Korean Intellectual Property Office, the entire content of which is incorporated by reference herein.

### BACKGROUND

### 1. Field

Embodiments of the disclosure relate to a display apparatus.

### 2. Description of the Related Art

Display apparatuses implement an image, and include liquid crystal displays (LCDs), organic light-emitting display (OLED) devices, and electrophoretic displays (EPDs). An electrode and other metal wires included in a display apparatus reflect light introduced from the outside. Therefore, display apparatuses have a problem in that visibility is low due to reflection of external light in a bright environment. To solve the above-described problem, a polarizing film, a color filter, and/or the like may be provided, and various studies are being conducted to improve visibility.

### SUMMARY

One or more embodiments include a display apparatus having excellent anti-reflection characteristics. However, the embodiments are only examples, and the scope of the disclosure is not limited thereto. Additional aspects of embodiments will be set forth in part in the description which follows and, in part, will be apparent from the description, or may be learned by practice of the presented embodiments of the disclosure.

According to one or more embodiments, a display apparatus includes a pixel electrode, an emission layer on the pixel electrode, an opposite electrode covering the emission layer, and a low-reflection layer on the opposite electrode and overlapping the emission layer, wherein the low-reflection layer includes molybdenum tantalum oxide (MoTaOₓ).

In an embodiment, the low-reflection layer may be in contact with the opposite electrode.

In an embodiment, the low-reflection layer may have a thickness of 150 Å to 450 Å.

In an embodiment, an amount of tantalum (Ta) in the low-reflection layer may be 2 at % to 16 at %.

In an embodiment, the opposite electrode may have a thickness of 80 Å to 150 Å.

In an embodiment, the opposite electrode may include a silver-magnesium ally (AgMg), and an amount of silver (Ag) in the opposite electrode may be 85 at % to 95 at %.

In an embodiment, the low-reflection layer may have blackening characteristics.

In an embodiment, a capping layer covering the low-reflection layer may be further included.

In an embodiment, a thickness of the low-reflection layer may be smaller than a thickness of the capping layer.

In an embodiment, a thin-film encapsulation layer on the low-reflection layer may be further included.

According to one or more embodiments, a display apparatus includes a pixel electrode, a pixel-defining layer having an opening that exposes at least a portion of the pixel electrode, an opposite electrode on the pixel electrode and the pixel-defining layer, a low-reflection layer in contact with the opposite electrode, and a thin-film encapsulation layer on the low-reflection layer, wherein the low-reflection layer includes molybdenum oxide having blackening characteristics, and the low-reflection layer has a thickness of 150 Å to 450 Å.

In an embodiment, the low-reflection layer may be on the opposite electrode.

In an embodiment, the low-reflection layer may include molybdenum tantalum oxide (MoTaOₓ).

In an embodiment, an amount of tantalum (Ta) in the low-reflection layer may be 2 at % to 16 at %.

In an embodiment, the low-reflection layer may have a refractive index of 1.8 to 2.2.

In an embodiment, the low-reflection layer may include at least one Group 5 element of the Periodic Table of Elements.

In an embodiment, an emission layer between the pixel electrode and the opposite electrode may be further included, and the emission layer may be in the opening of the pixel-defining layer.

In an embodiment, the low-reflection layer may overlap the emission layer.

In an embodiment, a capping layer on the low-reflection layer may be further included, and the capping layer may include a material different from that of the low-reflection layer.

In an embodiment, a thickness of the low-reflection layer may be smaller than a thickness of the capping layer.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic plan view of a portion of a display apparatus according to an embodiment;

FIG. 2 is an equivalent circuit diagram of a pixel included in the display apparatus of FIG. 1;

FIG. 3 is a schematic cross-sectional view of a portion of a display apparatus according to an embodiment;

FIG. 4 is a schematic cross-sectional view of an enlarged portion I of FIG. 3;

FIG. 5A is a graph and table showing a reflectance according to a thickness of a low-reflection layer;

FIG. 5B is a graph and table showing a reflectance when a thickness of an opposite electrode is different on a low-reflection layer having a constant thickness;

FIG. 6 is a schematic cross-sectional view of a portion of a display apparatus according to an embodiment;

FIG. 7 is a graph and table showing a reflectance according to a position of a low-reflection layer; and

FIG. 8 is a graph showing a transmittance of a low-reflection layer.

### DETAILED DESCRIPTION

Reference will now be made in more detail to embodiments of the present disclosure, examples of which are illustrated in the accompanying drawings, wherein like reference numerals refer to like elements throughout the present specification. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and example embodiments of the disclosure will be illustrated in the drawings and described in the detailed description section. The effect and features of embodiments of the present disclosure, and embodiments of methods to achieve the same, will be clearer referring to the detailed descriptions below with the drawings. However, embodiments of the present disclosure may be implemented in various suitable forms, and are not limited to the embodiments presented below.

Hereinafter, embodiments of the present disclosure will be described, in more detail, with reference to the accompanying drawings, and in the description with reference to the drawings, the same or corresponding components are indicated by the same reference numerals and redundant descriptions thereof may not be repeated.

In the following disclosure, it will be understood that although the terms “first,” “second,” etc. may be used herein to describe various components, these components should not be limited by these terms. These terms are only used to distinguish one component from another.

In the following embodiment, the expression of the singular in the specification includes the expression of the plural unless clearly specified otherwise in the context.

In the following disclosure, it will be further understood that the terms “comprises” and/or “comprising,” as used herein, specify the presence of stated features or components, but do not preclude the presence or addition of one or more other features or components.

In the following disclosure, it will be understood that when a layer, region, or component is referred to as being “formed on” another layer, region, or component, it can be directly or indirectly formed on the other layer, region, or component. That is, for example, intervening layers, regions, or components may be present.

In the following disclosure, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Sizes of components in the drawings may be exaggerated or reduced for convenience of explanation. In other words, because sizes and thicknesses of components in the drawings may be arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being “connected to” another layer, area, or component, it can be directly or indirectly connected to the other layer, region, or component. That is, for example, intervening layers, regions, or components may be present. For example, in the specification, when a layer, region, or component is electrically connected to another layer, region, or component, the layers, regions, or components may not only be directly electrically connected, but may also be indirectly electrically connected via another layer, region, or component therebetween.

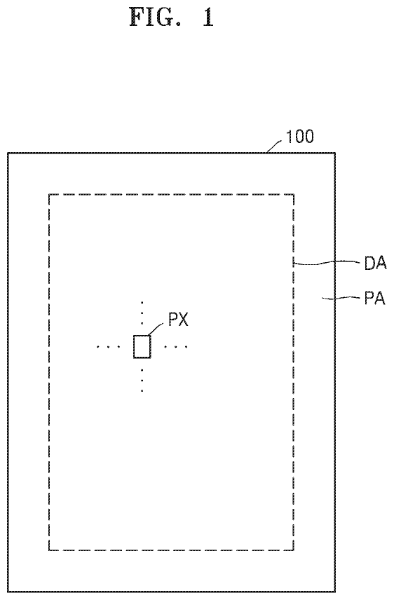

FIG. 1 is a schematic plan view of a display apparatus according to an embodiment.

A display apparatus displays an image and may be a portable mobile device, such as a game device, a multimedia device, and a miniature personal computer (PC). The display apparatus may include a liquid crystal display, an electrophoretic display, an organic light-emitting display, an inorganic electroluminescent (EL) display (for example, inorganic light-emitting display), a field emission display, a surface-conduction electron-emitter display, a quantum dot display, a plasma display, a cathode ray display, and/or the like. Hereinafter, although an organic light-emitting display is described as a display apparatus according to an embodiment, various types or kinds of display apparatuses as described above may be used in embodiments.

As shown in FIG. 1, the display apparatus may include a display area DA in which a plurality of pixels PX are arranged, and a peripheral area PA outside the display area DA. In more detail, the peripheral area PA may completely surround the display area DA, and it should be understood that a substrate 100 included in the display apparatus may have the display area DA and the peripheral area PA.

Each of the pixels PX of the display apparatus include an area from which light of a set or certain color is emitted, and the display apparatus may provide an image by using the light emitted from the pixels PX. For example, each pixel PX may emit red light, green light, or blue light. The pixel PX may further include a plurality of thin-film transistors and a storage capacitor to control a display element. The number of thin-film transistors included in one pixel may vary, for example, from 1 to 7.

The display area DA may have a polygonal shape including a quadrangle as shown in FIG. 1. For example, the display area DA may have a rectangular shape in which a horizontal length is greater than a vertical length, or a rectangular shape in which a horizontal length is less than a vertical length, or may have a square shape. In some embodiments, the display area DA may have various suitable shapes, such as an ellipse or a circle.

The peripheral area PA may be a non-display area in which the pixels PX are not arranged. A driver that provides an electrical signal or power to the pixels PX may be in the peripheral area PA. Pads to which electronic devices, printed circuit boards, and/or the like may be electrically connected may be in the peripheral area PA. The pads are spaced apart from each other in the peripheral area PA, and may each be electrically connected to a printed circuit board and/or an integrated circuit device. A thin-film transistor may be provided in the peripheral area PA, and at this time, the thin-film transistor in the peripheral area PA may be a part of a circuit unit for controlling an electrical signal applied to within the display area DA.

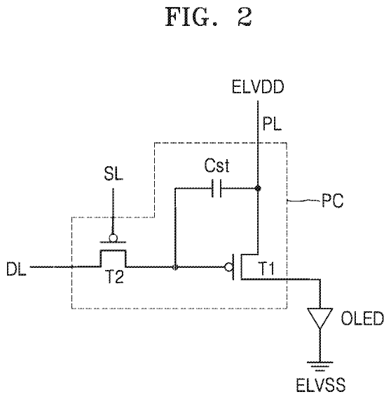

FIG. 2 is an equivalent circuit diagram of one pixel PX included in the display apparatus of FIG. 1.

As shown in FIG. 2, the pixel PX may include a pixel circuit PC and an organic light-emitting diode OLED electrically connected to the pixel circuit PC.

The pixel circuit PC may include a first thin-film transistor T1, a second thin-film transistor T2, and a storage capacitor Cst. The second thin-film transistor T2, as a switching transistor, may be connected to a scan line SL and a data line DL and may be turned on by a switching signal input from the scan line SL to transmit a data signal input from the data line DL to the first thin-film transistor T1. The storage capacitor Cst may have one end electrically connected to the second thin-film transistor T2 and the other end electrically connected to a driving voltage line PL, and may store a voltage corresponding to a difference between a voltage received from the second thin-film transistor T2 and a driving power voltage ELVDD supplied to the driving voltage line PL.

The first thin-film transistor T1, as a driving transistor, may be connected to the driving voltage line PL and the storage capacitor Cst, and may be configured to control a driving current flowing from the driving voltage line PL to the organic light-emitting diode OLED, according to a voltage value stored in the storage capacitor Cst. The organic light-emitting diode OLED may emit light having a set or certain luminance by the driving current. An opposite electrode of the organic light-emitting diode OLED may receive an electrode power voltage ELVSS.

FIG. 2 illustrates that the pixel circuit PC includes two transistors and one storage capacitor, but the disclosure is not limited thereto. For example, the number of transistors or the number of storage capacitors may vary according to the design of the pixel circuit PC.

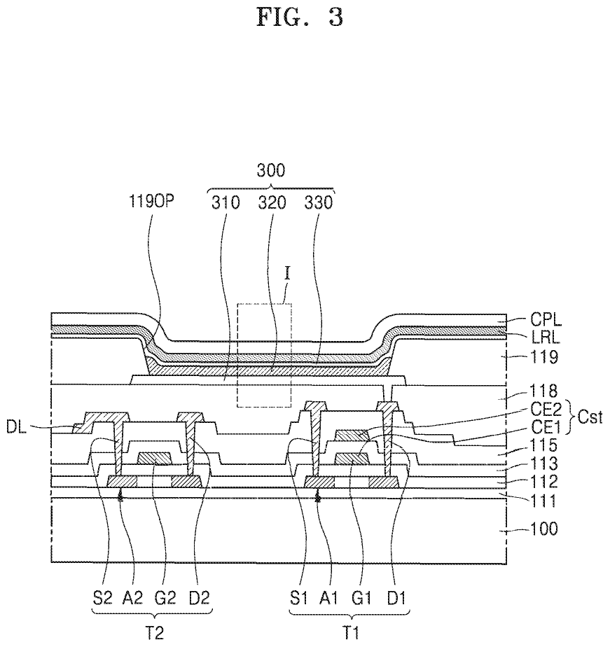

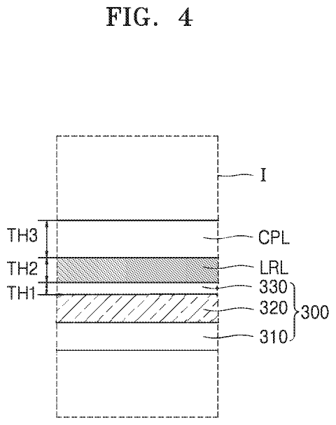

FIG. 3 is a schematic cross-sectional view of a portion of a display apparatus according to an embodiment, and FIG. 4 is an enlarged view of portion I of FIG. 3.

Referring to FIG. 3, the display apparatus includes a substrate 100, the first and second thin-film transistors T1 and T2, and an organic light-emitting diode 300 electrically connected to the first and second thin-film transistors T1 and T2. Also, an organic light-emitting display apparatus may further include various suitable insulating layers (for example, a buffer layer 111, a first gate insulating layer 112, a second gate insulating layer 113, an interlayer insulating layer 115, a planarization layer 118, and a pixel-defining layer 119) and the storage capacitor Cst.

The substrate 100 may be formed by using various suitable materials, such as a glass material, a metal material, and/or a plastic material. In an embodiment, the substrate 100 may be a flexible substrate, and may include, for example, a polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), and/or cellulose acetate propionate (CAP).

The buffer layer 111 may be on the substrate 100, and thus, may reduce or block infiltration of foreign substances, moisture, and/or external air from a lower portion of the substrate 100 and provide a flat surface on the substrate 100. The buffer layer 111 may include an inorganic material such as an oxide and/or a nitride, an organic material, or an organic/inorganic composite, and may be formed as a single-layer or multilayer structure of the inorganic material and/or the organic material. A barrier layer for preventing or reducing infiltration of external air may be further included between the substrate 100 and the buffer layer 111. In some embodiments, the buffer layer 111 may include a silicon oxide (SiO₂) and/or a silicon nitride (SiNₓ).

The first thin-film transistor T1 and/or the second thin-film transistor T2 may be on the buffer layer 111. The first thin-film transistor T1 includes a semiconductor layer A1, a gate electrode G1, a source electrode S1, and a drain electrode D1, and the second thin-film transistor T2 includes a semiconductor layer A2, a gate electrode G2, a source electrode S2, and a drain electrode D2. The first thin-film transistor T1 may function as a driving thin-film transistor connected to the organic light-emitting diode 300 to drive the organic light-emitting diode 300. The second thin-film transistor T2 may be connected to the data line DL to function as a switching thin-film transistor. In the drawings, there are two thin-film transistors, but the disclosure is not limited thereto. The number of thin-film transistors may vary, for example, from 1 to 7.

The semiconductor layers A1 and A2 may independently include amorphous silicon or polysilicon. In another embodiment, the semiconductor layers A1 and A2 may independently include an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layers A1 and A2 may include a channel region, and a source region and a drain region, which are doped with impurities.

The gate electrodes G1 and G2 are on the semiconductor layers A1 and A2 with the first gate insulating layer 112 therebetween. The gate electrodes G1 and G2 may independently include molybdenum (Mo), aluminum (Al), copper (Cu), and/or Ti, and may be formed as a single layer or a multilayer. For example, each of the gate electrodes G1 and G2 may be a single layer of Mo.

The first gate insulating layer 112 may include SiO₂, SiNₓ, a silicon oxynitride (SiON), an aluminum oxide (Al₂O₃), a titanium oxide (TiO₂), a tantalum oxide (Ta₂O₅), a hafnium oxide (HfO₂), and/or a zinc oxide (ZnO₂).

The second gate insulating layer 113 may cover the gate electrodes G1 and G2. The second gate insulating layer 113 may include SiO₂, SiNₓ, SiON, Al₂O₃, TiO₂, Ta₂O₅, HfO₂, and/or ZnO₂.

A first storage electrode CE1 of the storage capacitor Cst may overlap the first thin-film transistor T1. For example, the gate electrode G1 of the first thin-film transistor T1 may function as the first storage electrode CE1 of the storage capacitor Cst. However, the disclosure is not limited thereto. The storage capacitor Cst may not overlap the first thin-film transistor T1 and may be spaced apart from the first and second thin-film transistors T1 and T2.

A second storage electrode CE2 of the storage capacitor Cst overlaps the first storage electrode CE1 with the second gate insulating layer 113 therebetween. In this case, the second gate insulating layer 113 may function as a dielectric layer of the storage capacitor Cst. The second storage electrode CE2 may include a conductive material including Mo, Al, Cu, Ti, and/or the like, and may be formed as a multilayer or single layer including the above material. For example, the second storage electrode CE2 may be a single layer of Mo or a multilayer of Mo/Al/Mo.

The interlayer insulating layer 115 is on the entire surface of the substrate 100 to cover the second storage electrode CE2. The interlayer insulating layer 115 may include SiO₂, SiNₓ, SiON, Al₂O₃, TiO₂, Ta₂O₅, HfO₂, and/or ZnO₂.

The source electrodes S1 and S2 and the drain electrodes D1 and D2 are on the interlayer insulating layer 115. The source electrodes S1 and S2 and the drain electrodes D1 and D2 may include a conductive material (e.g., an electrically conductive material) including Mo, Al, Cu, Ti, and/or the like, and may be formed as a multilayer or single layer including the foregoing material. For example, each of the source electrodes S1 and S2 and the drain electrodes D1 and D2 may be formed as a multilayer structure of Ti/Al/Ti.

The planarization layer 118 may be on the source electrodes S1 and S2 and the drain electrodes D1 and D2, and the organic light-emitting diode 300 may be on the planarization layer 118. The organic light-emitting diode 300 includes a pixel electrode 310, an intermediate layer 320 including an organic emission layer, and an opposite electrode 330.

The planarization layer 118 may have a flat upper surface so that the pixel electrode 310 may be flat. The planarization layer 118 may be formed as a single layer or multilayer including an organic material and/or an inorganic material. The planarization layer 118 may include a general-purpose polymer such as benzocyclobutene (BCB), polyimide (PI), hexamethyldisiloxane (HMDSO), polymethylmethacrylate (PMMA), and/or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and/or a blend thereof. In some embodiments, the planarization layer 118 may include SiO₂, SiNₓ, SiON, Al₂O₃, TiO₂, Ta₂O₅, HfO₂, and/or ZnO₂. After the planarization layer 118 is formed, chemical mechanical polishing may be performed to provide a flat upper surface.

An opening exists in the planarization layer 118 to expose one of the source electrode S1 or the drain electrode D1 of the first thin-film transistor T1, and the pixel electrode 310 is in contact (e.g., physical contact) with the source electrode S1 or the drain electrode D1 through the opening to be electrically connected to the first thin-film transistor T1. The pixel electrode 310 includes a light-transmissive conductive layer including a light-transmissive conductive oxide, such as an indium tin oxide (ITO), an indium oxide (In₂O₃), and/or an indium zinc oxide (IZO), and a reflective layer including a metal, such as Al and/or silver (Ag). For example, the pixel electrode 310 may have a three-layered structure of ITO/Ag/ITO.

The pixel-defining layer 119 may be on the pixel electrode 310. The pixel-defining layer 119 defines a pixel by having an opening 1190P corresponding to each of subpixels, for example, the opening 1190P through which at least a central portion of the pixel electrode 310 is exposed. Also, the pixel-defining layer 119 may prevent or reduce occurrences of arc and/or the like from between an edge of the pixel electrode 310 and the opposite electrode 330 by increasing a distance therebetween. The pixel-defining layer 119 may include, for example, an organic material, such as PI and/or HMDSO.

A spacer may be above the pixel-defining layer 119. The spacer may be used to prevent or reduce mask imprinting that may occur during a mask process used or required for forming the intermediate layer 320 of the organic light-emitting diode 300. The spacer may include, for example, an organic material, such as PI and/or HMDSO. The spacer and the pixel-defining layer 119 may be concurrently (e.g., simultaneously) formed of the same material. In this case, a halftone mask may be used.

The intermediate layer 320 of the organic light-emitting diode 300 may include an emission layer. The organic emission layer may include an organic material including a fluorescent or phosphorescent material emitting red light, green light, blue light, or white light. The green light may be light of a wavelength band of 495 nm to 580 nm, the red light may be light of a wavelength band of 580 nm to 780 nm, and the blue light may be light of a wavelength band of 400 nm to 495 nm.

The organic emission layer may include a low molecular weight organic material and/or a polymer organic material, and a functional layer, such as a hole transport layer (HTL), a hole injection layer (HIL), an electron transport layer (ETL), and an electron injection layer (EIL), may selectively be further under and above the organic emission layer. The intermediate layer 320 may correspond to each of a plurality of pixel electrodes 310. However, the disclosure is not limited thereto. The intermediate layer 320 may have various suitable modifications such as, for example, including a layer that is integrally formed over the plurality of pixel electrodes 310.

Referring to FIGS. 3 and 4, the opposite electrode 330 may be over the display area DA and the peripheral area PA, and may be above the intermediate layer 320 and the pixel-defining layer 119. The opposite electrode 330 may be integrally formed with respect to a plurality of organic light-emitting diodes 300 to correspond to the plurality of pixel electrodes 310.

The opposite electrode 330 may cover the intermediate layer 320. The opposite electrode 330 may be a light-transmissive electrode or a reflective electrode. In an embodiment, the opposite electrode 330 may have a thickness of about 80 Å to about 150 Å. In some embodiments, the opposite electrode 330 may be a transparent or semi-transparent electrode, and may include a metal thin film having a small work function, which includes lithium (Li), calcium (Ca), lithium fluoride (LiF)/Ca, LiF/Al, Al, Ag, magnesium (Mg), and a compound thereof. Also, a transparent conductive oxide (TCO) film, such as ITO, IZO, ZnO, and/or In₂O₃, may be further on the metal thin film. In an embodiment, the opposite electrode 330 may include a silver-magnesium alloy (AgMg). In this case, an amount of Ag in the opposite electrode 330 may be about 85 at % to about 95 at % (e.g., based on 100 at % of the opposite electrode 330).

The opposite electrode 330 may be a reflective electrode, and thus, when the display apparatus is used in a place where there is a substantial amount of light, visibility may decrease due to reflection of external light. Therefore, a polarizing film may be above the opposite electrode 330 with at least one layer therebetween. However, in general, the polarizing film that prevents or reduce reflection may reduce light transmittance to about 50% or less. Therefore, more power may be required to compensate for luminance.

In the disclosure, a low-reflection layer LRL may be on the opposite electrode 330. The low-reflection layer LRL may be in contact (e.g., physical contact) with the opposite electrode 330. The low-reflection layer LRL may overlap the emission layer included in the intermediate layer 320. In an embodiment, the low-reflection layer LRL may have a thickness of about 150 Å to about 450 Å. The low-reflection layer LRL may be above the opposite electrode 330, and thus, may simply be deposited collectively with the opposite electrode 330 in the same deposition facility without a separate process facility.

The low-reflection layer LRL may include molybdenum oxide (MoO₂) having blackening characteristics. The blackening characteristics may mean light-absorbing characteristics. The low-reflection layer LRL may further include tantalum oxide (TaO_{X}). In other words, the low-reflection layer LRL may include molybdenum tantalum oxide (MoTaO_{X}). Because the low-reflection layer LRL includes TaO_{X}, process stability may be improved by supplementing the chemical resistance of the low-reflection layer LRL. In this case, an amount of tantalum (Ta) may be about 2 at % to about 16 at % (e.g., based on 100 at % of the low-reflection layer LRL). X of MoTaO_{X} may be 2.0 to 3.0. In another embodiment, the low-reflection layer LRL may include at least one oxide of Group 5 elements of the Periodic Table of Elements, in addition to Ta.

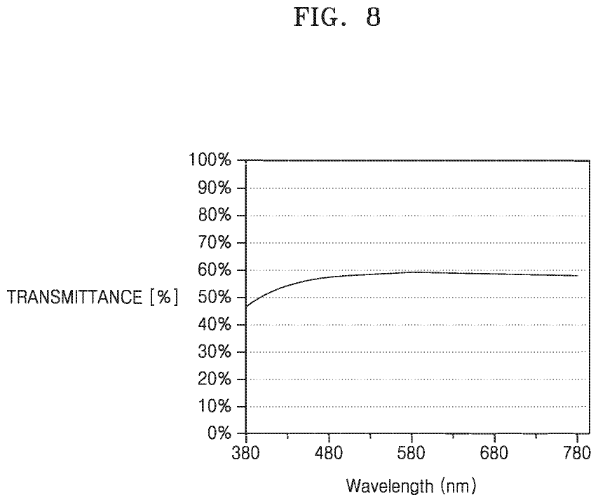

In other words, the low-reflection layer LRL may be provided as a layer having light-absorption properties and a small thickness, by adding TaOₓ to the composition of MoO₂ having blackening characteristics. As described with reference to FIG. 8, the low-reflection layer LRL may maintain a higher light transmittance than a general polarizing film. Accordingly, the display apparatus may prevent or reduce reflection of external light by arranging the low-reflection layer LRL without the polarizing film. However, the polarizing film may be further on the low-reflection layer LRL.

A capping layer CPL for improving light efficiency may be on the low-reflection layer LRL. The capping layer CPL may be a transparent layer. A thickness of the capping layer CPL may be about 750 Å to about 850 Å. The capping layer CPL may include an organic material, an inorganic material, or a mixture thereof. Examples of the organic material may include at least one selected from the group consisting of tris-8-hydroxyquinoline aluminum (Alq₃), ZnSe, 2,5-bis(6′-(2′,2″-bipyridyl))-1,1-dimethyl-3,4-diphenylsilole, 4′-bis[N-(1-naphthyl)-N-phenyl-amino]piphenyl (α-NPD), N,N′-diphenyl-N,N′-bis(3-methylphenyl)-1,1′-biphenyl-4,4′-diamine (TPD), 1,1′-bis(di-4-tolylaminophenyl) cyclohexane (TAPC), a triarylamine derivative (EL301), 8-quinolinolato lithium (Liq), N(diphenyl-4-yl)9,9-dimethyl-N-(4(9-phenyl[1]9H-carbazol-3-yl)phenyl)-9H-fluorene-2-amine (HT211), and 2-(4-(9,10-di(naphthalene-2-yl)anthracene-2-yl)phenyl)-1-phenyl-1H-benzo-[D]imidazole (LG201). Examples of the inorganic material may include at least one selected from the group consisting of ITO, IZO, SiO₂, SiNₓ, Y₂O₃, WO₃, and Al₂O₃. The low-reflection layer LRL and the capping layer CPL may include different materials. A light absorption rate of the low-reflection layer LRL may be greater than that of the capping layer CPL.

Referring to FIG. 4, a thickness TH1 of the opposite electrode 330 may be smaller than a thickness TH2 of the low-reflection layer LRL. The thickness TH2 of the low-reflection layer LRL may be smaller than a thickness TH3 of the capping layer CPL. The opposite electrode 330 may have a thickness of about 80 Å to about 150 Å. The low-reflection layer LRL may have a thickness of about 150 Å to about 450 Å. The capping layer CPL may have a thickness of about 800 Å.

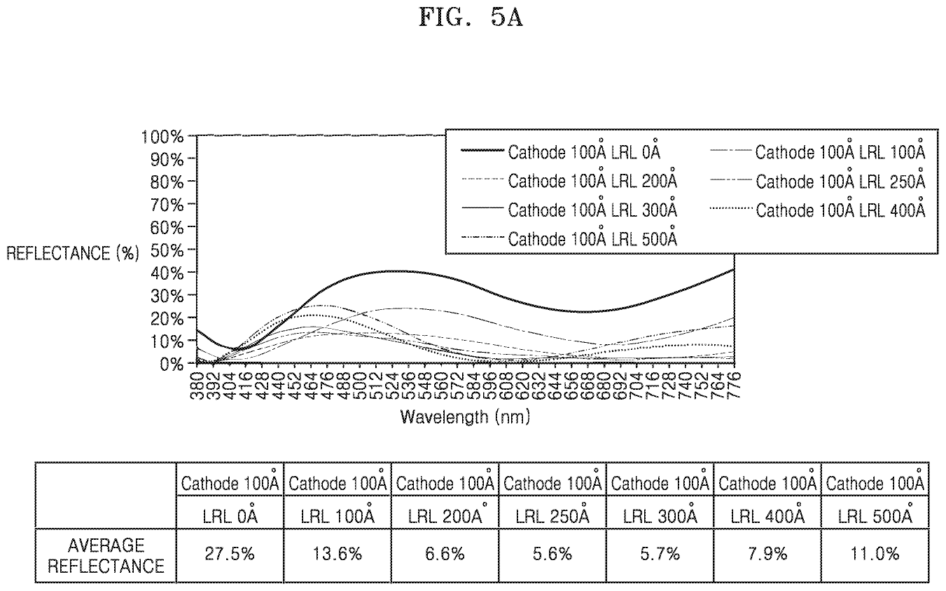

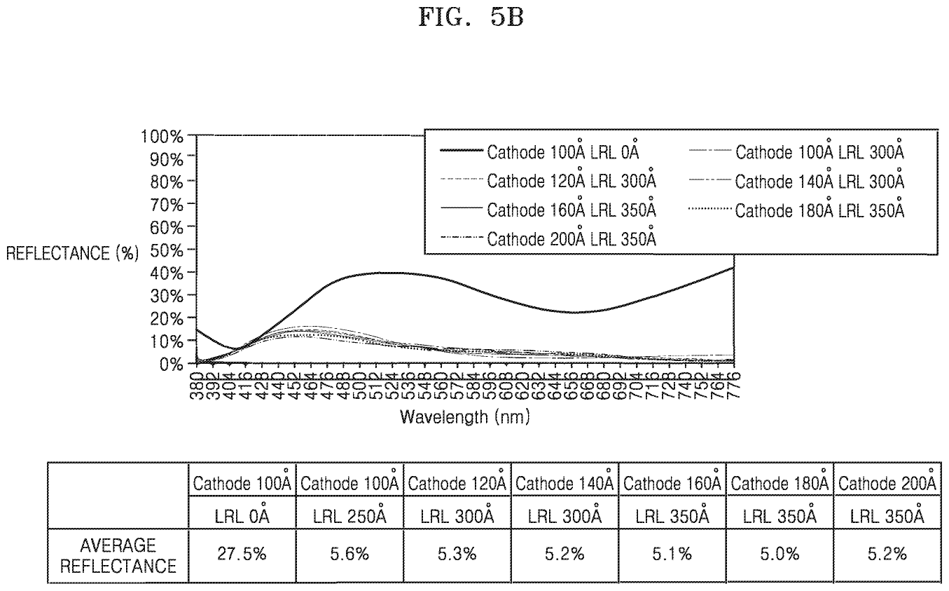

FIGS. 5A and 5B are graphs and tables showing a light reflectance according to thicknesses of the opposite electrode 330 and the low-reflection layer LRL.

FIG. 5A shows light reflectances according to a case where the low-reflection layer LRL was not on the opposite electrode 330 and a thickness of the low-reflection layer LRL on the opposite electrode 330. Experiments were carried out with the opposite electrode 330 having a thickness of about 100 Å.

The graph of FIG. 5A shows a reflectance according to a wavelength range of light for each thickness of the low-reflection layer LRL. The table of FIG. 5A shows an average reflectance according to a thickness of the low-reflection layer LRL.

Referring to FIG. 5A, when the low-reflection layer LRL on the opposite electrode 330 had a thickness of 100 Å to 500 Å, the maximum average reflectance was 13.6%. It can be seen that the average reflectance was significantly reduced compared to the average reflectance of 27.5% when the low-reflection layer LRL was not on the opposite electrode 330. When a thickness of the low-reflection layer LRL was about 250 Å, the average reflectance was 5.6%. In other words, the display apparatus may reduce external light reflectance by arranging, on the opposite electrode 330, the low-reflection layer LRL including an oxide including Mo. Accordingly, visibility of the display apparatus may be improved even in a bright environment.

In an embodiment, the low-reflection layer LRL may have a refractive index of 1.8 to 2.2. The low-reflection layer LRL may have a thickness of about 150 Å to about 450 Å. As such, because the low-reflection layer LRL may have a small thickness, the low-reflection layer LRL may have a small optical thickness (refractive index*thickness).

FIG. 5B shows a light reflectance according to a thickness of the opposite electrode 330. The graph of FIG. 5B shows a reflectance according to a wavelength range of light for each thickness of the opposite electrode 330. The table of FIG. 5B shows an average reflectance according to a thickness of the opposite electrode 330.

Referring to FIG. 5B, in experimental conditions in which the low-reflection layer LRL had relatively similar thicknesses, the average reflectance obtained by changing the thickness of the opposite electrode 330 to 100 Å, 120 Å, 140 Å, 160 Å, 180 Å, and 200 Å was 5.6%, 5.3%, 5.2%, 5.1%, 5.0%, and 5.2%, respectively, in a narrow range of 5.0% to 5.6%. This means that when the display apparatus has the low-reflection layer LRL having a thickness of about 250 Å to about 350 Å, anti-reflection characteristics may be maintained even when the thickness of the opposite electrode 330 is changed.

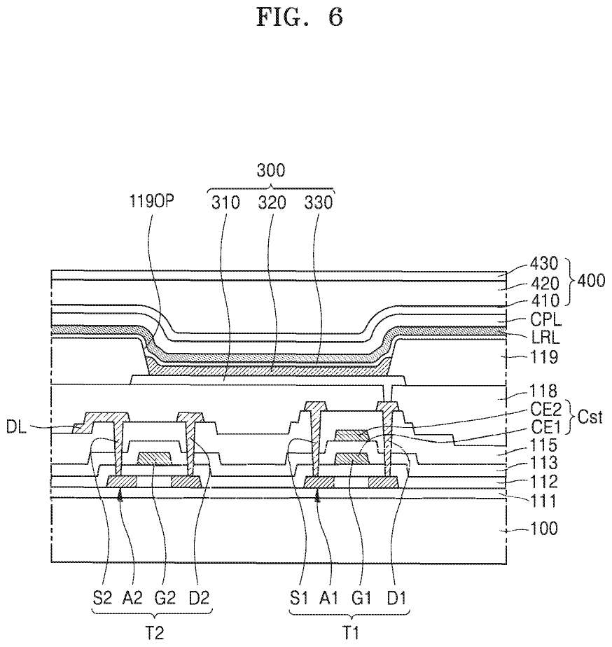

FIG. 6 is a schematic cross-sectional view of a portion of a display apparatus according to an embodiment. Redundant descriptions of the above-described components included in FIG. 3 are not repeated here.

A thin-film encapsulation (TFE) layer 400 that seals the display area DA may be further included above the organic light-emitting diode 300. The TFE layer 400 may cover the display area DA to protect the organic light-emitting diode 300 and/or the like from external moisture and/or oxygen. The TFE layer 400 may include a first inorganic encapsulation layer 410, an organic encapsulation layer 420, and a second inorganic encapsulation layer 430.

The first inorganic encapsulation layer 410 covers the opposite electrode 330, and may include ceramic, a metal oxide, a metal nitride, a metal carbide, a metal oxynitride, In₂O₃, a tin oxide (SnO₂), ITO, SiO₂, SiNₓ, and/or SiON. As necessary or desired, other layers, such as a capping layer, may be between the first inorganic encapsulation layer 410 and the opposite electrode 330. The first inorganic encapsulation layer 410 is formed along a structure thereunder, and thus, does not have a flat upper surface as shown in FIG. 13.

The organic encapsulation layer 420 covers the first inorganic encapsulation layer 410, and unlike the first inorganic encapsulation layer 410, may have an approximately flat upper surface. In more detail, a portion of the organic encapsulation layer 420, which corresponds to the display area DA, may have an approximately flat upper surface. The organic encapsulation layer 420 may include at least one material selected from the group consisting of acryl, methacrylic, polyester, polyethylene, polypropylene, PET, PEN, PC, PI, polyethylene sulfonate, polyoxymethylene, polyarylate, and HMDSO.

The second inorganic encapsulation layer 430 covers the organic encapsulation layer 420, and may include ceramic, a metal oxide, a metal nitride, a metal carbide, a metal oxynitride, In₂O₃, SnO₂, ITO, SiO₂, SiNₓ, and/or SiON. The second inorganic encapsulation layer 430 may be in contact (e.g., physical contact) with the first inorganic encapsulation layer 410 at its edge outside the display area DA, thereby preventing or reducing exposure of the organic encapsulation layer 420 to the outside.

As such, the TFE layer 400 includes the first inorganic encapsulation layer 410, the organic encapsulation layer 420, and the second inorganic encapsulation layer 430, and thus, even when cracks occur in the TFE layer 400 via such a multilayer structure, the cracks may not be connected to each other between the first inorganic encapsulation layer 410 and the organic encapsulation layer 420 or between the organic encapsulation layer 420 and the second inorganic encapsulation layer 430. Accordingly, the formation of a path through which moisture and/or oxygen from the outside penetrates into the display area DA may be prevented, minimized, or reduced.

In the present embodiment, the TFE layer 400 is used as an encapsulation member that seals the organic light-emitting diode 300, but the disclosure is not limited thereto. For example, as a member that seals the organic light-emitting diode 300, a sealing substrate bonded to the substrate 100 by a sealant and/or a frit may be used.

Referring to FIG. 6, in an embodiment, the low-reflection layer LRL may be under the capping layer CPL or the TFE layer 400. In other words, the low-reflection layer LRL may be above the opposite electrode 330 and may be in contact (e.g., physical contact) with the opposite electrode 330. In this case, in a facility for depositing the opposite electrode 330, the low-reflection layer LRL may simply be deposited collectively with the opposite electrode 330.

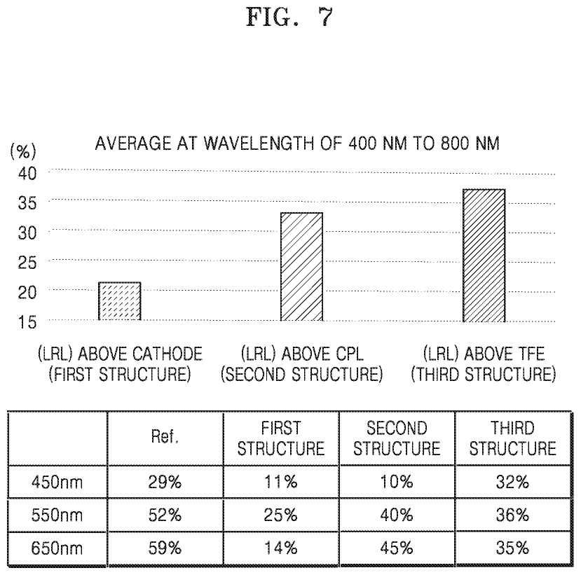

FIG. 7 shows a light reflectance according to a position of the low-reflection layer LRL. A graph included in FIG. 7 shows an average light reflectance according to a wavelength for each position of the low-reflection layer LRL. A table included in FIG. 7 shows light reflectances at specific wavelengths (450 nm, 550 nm, and 650 nm) for each position of the low-reflection layer LRL. A comparative example (Ref) is a case where the low-reflection layer LRL was not provided in the display apparatus.

In an embodiment, the low-reflection layer LRL may be above the opposite electrode 330 as shown in FIG. 6. An experiment structure of FIG. 7 includes a structure (hereinafter, referred to as a first structure) where the low-reflection layer LRL was between the opposite electrode 330 and the capping layer CPL, a structure (hereinafter, referred to as a second structure) where the low-reflection layer LRL was between the capping layer CPL and the TFE layer 400, and a structure (hereinafter, referred to as a third structure) where the low-reflection layer LRL was above the TFE layer 400.

Referring to the graph of FIG. 7, an average reflectance at a wavelength of 400 nm to 800 nm was about 21% for the first structure, about 33% for the second structure, and about 37% for the third structure. In other words, among the comparative structures, when the low-reflection layer LRL was directly on the opposite electrode 330, an effect of preventing or reducing reflection of external light was the greatest. Referring to the table of FIG. 7, even in various suitable wavelength ranges of 450 nm, 550 nm, and 650 nm, mostly, the first structure exhibited lower reflectance than other structures.

Referring to FIG. 6, the display apparatus according to an embodiment may include the opposite electrode 330 and the low-reflection layer LRL being in contact (e.g., physical contact) with the opposite electrode 330 and including MoO₂ having blackening characteristics. The low-reflection layer LRL may be on the opposite electrode 330. The capping layer CPL may be on the low-reflection layer LRL. The TFE layer 400 may be on the capping layer CPL. In other words, in an embodiment, the low-reflection layer LRL between the opposite electrode 330 and the capping layer CPL may be included. Accordingly, referring to FIG. 7, the display apparatus may have significantly reduced light reflectance.

FIG. 8 is a graph showing a light transmittance of a display apparatus in which the low-reflection layer LRL having a thickness of 250 Å is arranged.

Generally, in a display apparatus, a polarizing film and/or the like may be above the TFE layer 400 to reduce reflection of external light. When a separate layer is arranged to prevent or reduce reflection of external light, a light transmittance may be reduced, and thus, the luminance of the display apparatus may be reduced. More power may be consumed to compensate for the luminance. In general, the polarizing film that prevents or reduces reflection of external light may reduce light transmittance by 50% or more.

In an embodiment, the low-reflection layer LRL including MoO₂ may be above the opposite electrode 330. The low-reflection layer LRL may include MoTaOₓ. The low-reflection layer LRL may have a thickness of about 150 Å to about 450 Å. In other words, the low-reflection layer LRL may be provided as a layer having light-absorption properties and a small thickness, by adding TaOₓ to the composition of MoO₂ having blackening characteristics.

Referring to FIG. 8, the display apparatus according to an embodiment may maintain a light transmittance close to 60% in a wavelength range of 480 nm to 780 nm. Accordingly, the display apparatus according to an embodiment may realize required or desired luminance with relatively low power.

According to an embodiment as described above, the display apparatus includes the low-reflection layer, and thus, has excellent anti-reflection characteristics and excellent visibility. However, the above-described effects are examples.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims, and equivalents thereof.

What is claimed is:

1. A display apparatus comprising:
a pixel electrode;
an emission layer on the pixel electrode;
an opposite electrode covering the emission layer; and
a low-reflection layer on the opposite electrode and overlapping the emission layer,
wherein the low-reflection layer comprises molybdenum tantalum oxide.

2. The display apparatus of claim 1, wherein the low-reflection layer is in contact with the opposite electrode.

3. The display apparatus of claim 1, wherein the low-reflection layer has a thickness of 150 Å to 450 Å.

4. The display apparatus of claim 1, wherein an amount of tantalum (Ta) in the low-reflection layer is 2 at % to 16 at %.

5. The display apparatus of claim 1, wherein the opposite electrode has a thickness of 80 Å to 150 Å.

6. The display apparatus of claim 5, wherein the opposite electrode comprises a silver-magnesium alloy (AgMg), and
an amount of silver (Ag) in the opposite electrode is 85 at % to 95 at %.

7. The display apparatus of claim 1, wherein the low-reflection layer has blackening characteristics.

8. The display apparatus of claim 1, further comprising a capping layer covering the low-reflection layer.

9. The display apparatus of claim 8, wherein a thickness of the low-reflection layer is smaller than a thickness of the capping layer.

10. The display apparatus of claim 1, further comprising a thin-film encapsulation layer on the low-reflection layer.

11. A display apparatus comprising:
a pixel electrode;
a pixel-defining layer having an opening that exposes at least a portion of the pixel electrode;
an opposite electrode on the pixel electrode and the pixel-defining layer;
a low-reflection layer in contact with the opposite electrode; and
a thin-film encapsulation layer on the low-reflection layer,
wherein the low-reflection layer comprises molybdenum having blackening characteristics and an oxide including a Group 5 element of the Periodic Table of Elements, and
the low-reflection layer has a thickness of 150 Å to 450 Å.

12. The display apparatus of claim 11, wherein the low-reflection layer is on the opposite electrode.

13. The display apparatus of claim 11, wherein the low-reflection layer comprises molybdenum tantalum oxide.

14. The display apparatus of claim 13, wherein an amount of tantalum (Ta) in the low-reflection layer is 2 at % to 16 at %.

15. The display apparatus of claim 11, wherein the low-reflection layer has a refractive index of 1.8 to 2.2.

16. The display apparatus of claim 13, further comprising an emission layer between the pixel electrode and the opposite electrode,
wherein the emission layer is in the opening of the pixel-defining layer.

17. The display apparatus of claim 16, wherein the low-reflection layer overlaps the emission layer.

18. The display apparatus of claim 11, further comprising a capping layer on the low-reflection layer.

19. The display apparatus of claim 18, wherein the capping layer comprises a material different from that of the low-reflection layer.

20. The display apparatus of claim 18, wherein a thickness of the low-reflection layer is smaller than a thickness of the capping layer.
